(19) United States
(12) Patent Application Publication
(10) Pub. No.: US 2023/0180557 A1
(43) Pub. Date: Jun. 8, 2023

(54) DISPLAY PANEL AND DISPLAY DEVICE

(71) Applicant: Xiamen Tianma Display Technology Co., Ltd., Xiamen (CN)

(72) Inventors: Fenxiang ZOU, Xiamen (CN); Jieliang LI, Xiamen (CN); Yong YUAN, Xiamen (CN)

(73) Assignee: Xiamen Tianma Display Technology Co., Ltd., Xiamen (CN)

(21) Appl. No.: 18/103,719

(22) Filed: Jan. 31, 2023

(30) Foreign Application Priority Data
Jun. 30, 2022 (CN) 202210772975.0

(51) Int. Cl. H10K 59/131

(52) U.S. Cl. CPC H10K 59/131

(57) ABSTRACT

Provided are a display panel and a display device. The display panel includes a fan-out region. The fan-out region includes multiple fan-out data lines. The multiple fan-out data lines include at least three layers of fan-out data lines disposed in different layers.

### CROSS-REFERENCE TO RELATED APPLICATION(S)

This application claims priority to Chinese Patent Application No. 202210772975.0 filed Jun. 30, 2022, the disclosure of which is incorporated herein by reference in its entirety.

### TECHNICAL FIELD

The present disclosure relates to the field of display technologies and, in particular, to a display panel and a display device.

### BACKGROUND

With the development of display technologies, people require a higher and higher display resolution of a display screen. A higher display resolution requires a large number of signal lines to be disposed in a display panel. This increases the space occupied by the lower bezel region in the display panel and is not conducive to an increase in the screen-to-body ratio of the display panel.

### SUMMARY

Embodiments of the present disclosure provide a display panel and a display device.

In a first aspect, embodiments of the present disclosure provide a display panel. The display panel includes a fan-out region. The fan-out region includes a plurality of fan-out data lines. The plurality of fan-out data lines include at least three layers of fan-out data lines disposed in different layers.

In a second aspect, embodiments of the present disclosure also provide a display device. The display device includes the display panel described in the first aspect.

### BRIEF DESCRIPTION OF DRAWINGS

FIG. 1 is a diagram illustrating the structure of a display panel according to embodiments of the present disclosure.

FIG. 2 is a sectional view of the structure of the display panel of FIG. 1 taken along section line A-A′.

FIG. 3 is another sectional view of the structure of the display panel of FIG. 1 taken along section line A-A′.

FIG. 4 is another sectional view of the structure of the display panel of FIG. 1 taken along section line A-A′.

FIG. 5 is a diagram illustrating the structure of another display panel according to embodiments of the present disclosure.

FIG. 6 is a diagram illustrating the structure of another display panel according to embodiments of the present disclosure.

FIG. 7 is a diagram illustrating the structure of another display panel according to embodiments of the present disclosure.

FIG. 8 is a diagram illustrating the structure of another display panel according to embodiments of the present disclosure.

FIG. 9 is a diagram illustrating the structure of another display panel according to embodiments of the present disclosure.

FIG. 10 is a diagram illustrating the structure of another display panel according to embodiments of the present disclosure.

FIG. 11 is a diagram illustrating the structure of another display panel according to embodiments of the present disclosure.

FIG. 12 is a sectional view of the structure of the display panel of FIG. 1 taken along section line B-B′.

FIG. 13 is another sectional view of the structure of the display panel of FIG. 1 taken along section line B-B′.

FIG. 14 is a diagram illustrating the structure of a display device according to embodiments of the present disclosure.

### DETAILED DESCRIPTION

To illustrate the technical solutions in the embodiments of the present disclosure or the technical solutions in the related art more clearly, drawings used in the description of the embodiments or the related art will be briefly described below. Apparently, though the drawings described below illustrate part of specific embodiments of the present disclosure, those skilled in the art may expand and extend to other structures and drawings according to the basic concepts of the device structure, driving method, and manufacturing method disclosed and indicated in the embodiments of the present disclosure. These are undoubtedly all within the scope of the claims of the present disclosure.

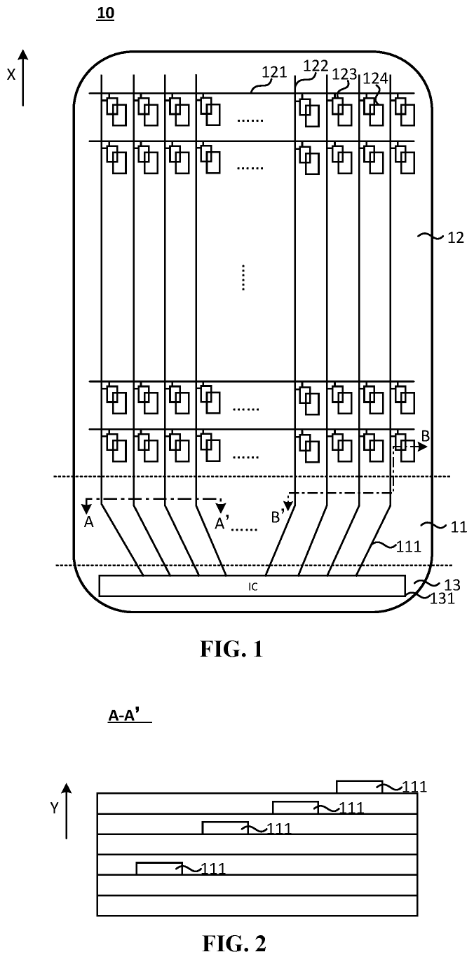

FIG. 1 is a diagram illustrating the structure of a display panel according to embodiments of the present disclosure. FIG. 2 is a sectional view of the structure of the display panel of FIG. 1 taken along section line A-A′. As shown in FIGS. 1 and 2, the display panel 10 according to this embodiment of the present disclosure includes a fan-out region 11. The fan-out region 11 includes multiple fan-out data lines 111. The multiple fan-out data lines 111 include at least three layers of fan-out data lines disposed in different layers.

As shown in FIG. 1, the display panel 10 according to this embodiment of the present disclosure includes a display region 12. The display region 12 includes scan lines 121, data lines 122, pixel circuits 123, and light-emitting sub-pixels 124. A scan line 121 and a data line 122 define the positions of a pixel circuit 123 and a light-emitting sub-pixel 124. Specifically, the pixel circuits 123 and the light-emitting sub-pixels 124 are arranged in an array, a scan line 121 is electrically connected to pixel circuits 123 disposed in the same row as the scan line 121, a data line 122 is electrically connected to pixel circuits 123 disposed in the same column as the data line 122, and a pixel circuit is configured to transmit, under the control of a scan signal input by a scan line 121, a data signal supplied by a data line 122 to a light-emitting sub-pixel 124 to drive the light-emitting sub-pixel 124 to emit light. In an embodiment, a light-emitting sub-pixel 124 according to this embodiment of the present disclosure may be a light-emitting element of the organic light-emitting diode type or a light-emitting element of the micro light-emitting diode type, for example, micro-led or mini-led. The specific type of the light-emitting sub-pixel 124 is not limited in this embodiment of the present disclosure. In an embodiment, a pixel circuit 123 may include a storage capacitor and a thin-film transistor. For example, the pixel circuit 123 may include a storage capacitor and two thin-film transistors to form a “2T1C” light emission circuit or may include a storage capacitor and seven thin-film transistors to form a “7T1C” light emission circuit. The specific structure of the pixel circuit 123 is not limited in this embodiment of the present disclosure.

With continued reference to FIG. 1, the display panel 10 according to this embodiment of the present disclosure also includes the fan-out region 11 and a bonding region 13. The fan-out region 11 is provided with the multiple fan-out data lines 111. The bonding region 13 is provided with a driver chip 131. A fan-out data line 111 is electrically connected to a data line 122 and the driver chip 131 for transmitting a data signal supplied by the driver chip 131 to the data line 122. As the pixel resolution gradually increases, the distribution density of light-emitting sub-pixels 124 disposed in the display region 12 gradually increases so that the number of data lines 122 disposed in the display region 12 is also gradually increased, and thereby the number of fan-out data lines 111 electrically connected to the data lines 122 is also gradually increased. As shown in FIG. 1, the fan-out data lines 111 include a portion that is the same as the extension direction (the X direction shown in the figure) of the data lines 122 and a portion that intersects the extension direction of the data lines 122. Among the fan-out data lines 111, the portion that intersects the extension direction of the data lines 122 needs to occupy a larger space in the extension direction of the data lines 122, resulting in a larger area occupied by the fan-out region 11 and affecting the narrow bezel design of the display panel 10. Based on this, the configuration in which the multiple fan-out data lines 111 include the at least three layers of fan-out data lines disposed in different layers is inventively provided in this embodiment of the present disclosure. The space for disposing the fan-out data lines 111 can be reduced by stacking the fan-out data lines 111 so that the narrow bezel design of the display panel can be achieved, and thereby the screen-to-body ratio of the display panel can be increased.

It is to be noted that the fan-out data lines 111 include the at least three layers of fan-out data lines disposed in different layers, and among the at least three layers of fan-out data lines disposed in different layers, at least two layers of fan-out data lines may overlap in the thickness direction of the display panel so that the space for disposing the fan-out data lines can be further reduced, and thereby the narrow bezel design of the display panel can be achieved. Any two layers of fan-out data lines may not overlap in the thickness direction of the display panel. Compared with the solution in which the fan-out data lines are disposed in the same layer, the fan-out data lines disposed in different layers do not need to consider the intervals between the fan-out data lines so that the space for disposing the fan-out data lines can also be reduced, and thereby the narrow bezel design of the display panel can be achieved.

It is also to be noted that the multiple fan-out data lines 111 shown in FIG. 1 are merely intended to show the connection mode between the fan-out data lines 111, the data lines 122, and the driver chip 131 and do not limit whether the fan-out data lines 111 disposed in different layers overlap in the thickness direction of the display panel.

It is also to be noted that the bonding region 13 may be disposed on the light emission side of the display panel 10 as shown in FIG. 1, or may be bent to the light nonemission side of the display panel 10 (not shown in the figure) so that the mark of the lower bezel of the display panel can be reduced, and thereby the narrow bezel design of the display panel can be achieved. The specific configuration mode of the bonding region is not limited in this embodiment of the present disclosure.

It is also to be noted that a light-emitting panel according to this embodiment of the present disclosure may also include other films and structures to ensure that the light-emitting panel can normally emit light. The specific structure of the light-emitting panel is not limited in this embodiment of the present disclosure.

In conclusion, in the display panel according to this embodiment of the present disclosure, the fan-out data lines include the at least three layers of fan-out data lines disposed in different layers so that the space for disposing the fan-out data lines can be reduced, the space occupied by the fan-out region can be reduced, and thereby the screen-to-body ratio of the display panel can be increased.

In an embodiment, with continued reference to FIG. 2, any two layers of fan-out data lines 111 disposed in different layers are staggered in the thickness direction (the Y direction shown in the figure) of the display panel.

Specifically, any two layers of fan-out data lines 111 disposed in different layers are staggered in the thickness direction of the display panel, that is, there is no overlapping region between the any two layers of fan-out data lines 111 in the thickness direction of the display panel, so that a parasitic capacitance cannot be generated between the any two layers of fan-out data lines disposed in different layers. Therefore, any layer of fan-out data lines 111 cannot affect a data signal transmitted on the any layer of fan-out data lines 111 due to the interference of a parasitic capacitance so that the data signal transmission process can be protected from the interference of the parasitic capacitance, the precision of data signal transmission can be high, and the display effect can be good.

Further, the any two layers of fan-out data lines 111 disposed in different layers are staggered, that is, multiple layers of fan-out data lines 111 disposed in different layers are laid flat on the plane on which the display panel is located, that is, there is only one layer of fan-out data lines 111 in each different position of the fan-out region, so that the film thickness of the display panel in the fan-out region can be well balanced, a flatter environment for disposing the upper films of the multiple fan-out data lines 111 can be provided, and the preparation of the upper films can be facilitated.

It is to be noted that, as described in the preceding, though the any two layers of fan-out data lines do not overlap in the thickness direction of the display panel, compared with the solution in which the fan-out data lines are disposed in the same layer, the fan-out data lines disposed in different layers do not need to consider the intervals between the fan-out data lines. For example, the intervals between the fan-out data lines disposed in different layers are zero or smaller than the minimum process value between the existing fan-out data lines disposed in the same layer so that the space for disposing the fan-out data lines can also be reduced, and thereby the narrow bezel design of the display panel can be achieved.

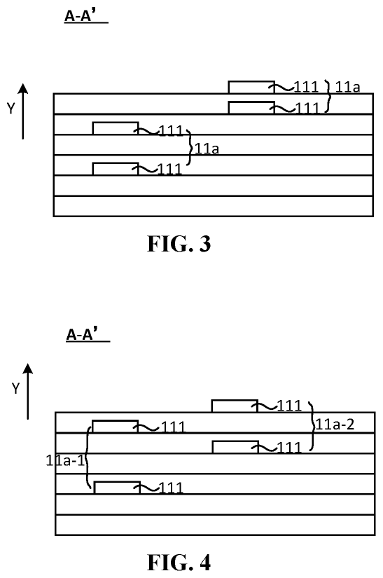

In an embodiment, FIG. 3 is another sectional view of the structure of the display panel of FIG. 1 taken along section line A-A′, and FIG. 4 is another sectional view of the structure of the display panel of FIG. 1 taken along section line A-A′. As shown in FIGS. 3 and 4, two layers of fan-out data lines 111 disposed in different layers overlap in the thickness direction (the Y direction shown in the figure) of the display panel.

Specifically, as shown in FIG. 3, two layers of fan-out data lines 111 disposed in different layers overlap in the thickness direction of the display panel so that by overlapping the fan-out data lines, the space for disposing the fan-out data lines 111 can be further reduced, the area of the fan-out region can be further reduced, the narrow bezel design of the display panel can be further achieved, and thereby the screen-to-body ratio of the display panel can be increased.

It is to be noted that FIGS. 3 and 4 illustrate that two layers of fan-out data lines overlap in the thickness direction of the display panel. It is to be understood that multiple layers (for example, three layers or four layers) of fan-out data lines may also overlap in the thickness direction of the display panel so that the space for disposing the fan-out data lines 111 can be further reduced, the area of the fan-out region can be further reduced, and thereby the narrow bezel design of the display panel can be further achieved.

Based on the preceding embodiment, with continued reference to FIGS. 3 and 4, the fan-out region 11 includes at least two fan-out data line groups 11a, and each fan-out data line group 11a includes at least two layers of fan-out data lines 111; in the thickness direction (the Y direction shown in the figure) of the display panel, fan-out data lines 111 in the same fan-out data line group 11a overlap, and fan-out data lines 111 in different fan-out data line groups 11a are staggered.

Specifically, with continued reference to FIGS. 3 and 4, fan-out data lines 111 in the same fan-out data line group 11a overlap so that by overlapping the fan-out data lines in the same fan-out data line group 11a, the space for disposing the fan-out data lines 111 can be further reduced, the area of the fan-out region can be further reduced, and thereby the narrow bezel design of the display panel can be further achieved.

Further, fan-out data lines 111 in different fan-out data line groups 11a are staggered, so the at least two fan-out data line groups 11a disposed in different groups are laid flat on the plane on which the display panel is located, that is, there is only one fan-out data line group 11a in each different position of the fan-out region, so that the film thickness of the display panel in the fan-out region can be well balanced, a flatter environment for disposing the upper films of the fan-out data lines 111 can be provided, and the preparation of the upper films can be facilitated.

Based on the preceding embodiment, with continued reference to FIG. 4, for each fan-out data line group 11a, a space between two layers of fan-out data lines 111 adjacent to each other in the thickness direction (the Y direction shown in the figure) of the display panel and included in a fan-out data line group 11a contains fan-out data lines 111 in another fan-out data line group 11a.

Exemplarily, FIG. 4 illustrates that the at least two fan-out data line groups 11a include a first fan-out data line group 11a-1 and a second fan-out data line group 11a-2, and each fan-out data line group 11a includes two layers of fan-out data lines 111. As shown in FIG. 4, two layers of fan-out data lines 111 in the first fan-out data line group 11a-1 are not fan-out data lines located in successively adjacent films in the thickness direction of the display panel, and similarly, two layers of fan-out data lines 111 in the second fan-out data line group 11a-2 are not fan-out data lines located in successively adjacent films in the thickness direction of the display panel. That is, in the thickness direction of the display panel, the fan-out data lines in the first fan-out data line group 11a-1 and the fan-out data lines in the second fan-out data line group 11a-2 are fan-out data lines 111 located in successively adjacent films. That is, for the each fan-out data line group 11a, the space between the two layers of fan-out data lines 111 adjacent to each other in the thickness direction of the display panel and included in the fan-out data line group 11a contains the fan-out data lines 111 in the another fan-out data line group 11a. Briefly, the first fan-out data line group 11a-1 includes a fan-out data line 111 located in the first film and a fan-out data line 111 located in the third film, and the second fan-out data line group 11a-2 includes a fan-out data line 111 located in the second film and a fan-out data line 111 located in the fourth film. Therefore, on one hand, the space for disposing the fan-out data lines 111 can be further reduced by overlapping the fan-out data lines in the same fan-out data line group 11a, on the other hand, the same number of films of fan-out data lines 111 in each different position of the fan-out region is ensured so that the film thickness of the display panel in the fan-out region can be well balanced, and on the other hand, the fan-out data lines 111 located in successively adjacent films are ensured not to overlap in the thickness direction of the display panel so that the mutual interference between the fan-out data lines 111 located in successively adjacent films caused by parasitic capacitances can be reduced, the precision of data signal transmission can be high, and the display effect can be good.

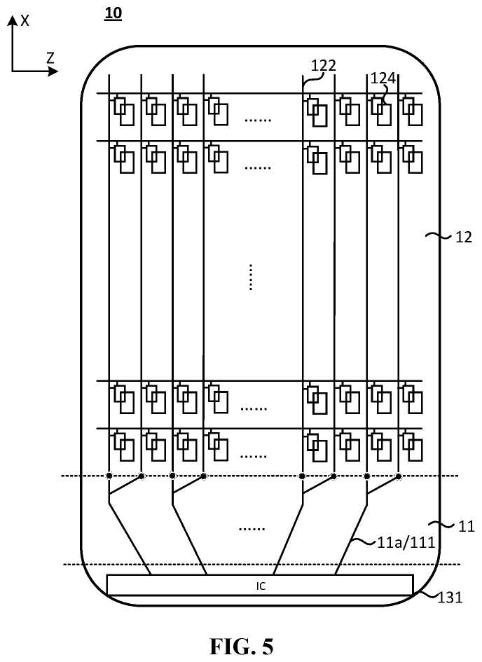

Based on the preceding embodiment, FIG. 5 is a diagram illustrating the structure of another display panel according to embodiments of the present disclosure. As shown in FIG. 5, the display panel 10 also includes a display region 12, and the fan-out region 11 is located on one side of the display region 12; the display panel 10 also includes data lines 122 located in the display region, and the data lines 122 extend in the first direction (the X direction shown in the figure) and are arranged in the second direction (the Z direction shown in the figure); and among the data lines 122, data lines 122 connected to the fan-out data lines 111 in the same fan-out data line group 11 a are adjacent in the second direction.

Specifically, as shown in FIG. 5, the display panel 10 also includes a display region 12 and data lines 122 located in the display region 12. The data lines 122 extend in the first direction (the X direction shown in the figure) and are arranged in the second direction (the Z direction shown in the figure). A fan-out data line 111 is electrically connected to data lines 122 and the driver chip 131 so that a data signal supplied by the driver chip 131 can be transmitted to the data lines 122 through the fan-out data line 111 to drive light-emitting sub-pixels 124 to normally emit light for display. In this embodiment of the present disclosure, the data lines 122 connected to the fan-out data lines 111 in the same fan-out data line group 11a are adjacent in the second direction so that when being electrically connected to the data lines 122, the fan-out data lines 111 in the same fan-out data line group 11a cannot overlap the fan-out data lines 111 in other fan-out data line groups 11a; and so that the fan-out data lines 111 in different fan-out data line groups 11a cannot generate parasitic capacitances due to mutual overlapping, the mutual interference between the fan-out data lines 111 in different fan-out data line groups 11a caused by the parasitic capacitances can be prevented, the precision of data signal transmission can be high, and the display effect can be good.

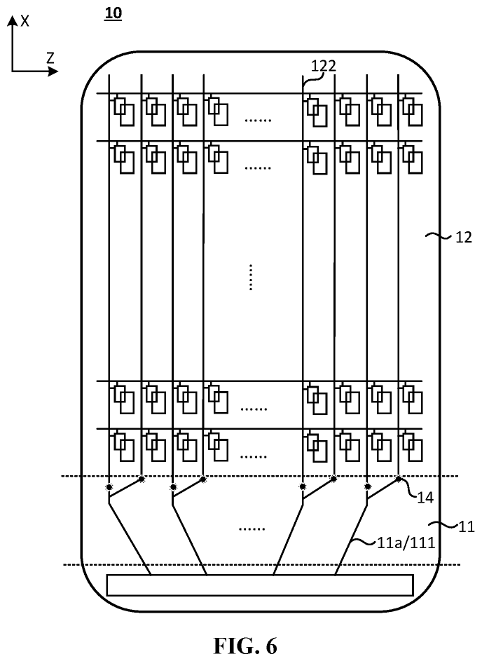

Based on the preceding embodiment, FIG. 6 is a diagram illustrating the structure of another display panel according to embodiments of the present disclosure. As shown in FIG. 6, a data line 122 is electrically connected to a fan-out data line 111 through a connection via 14, and connection vias 14 through which the fan-out data lines 111 in the same data line group 11a are connected to the data lines 122 are staggered in the first direction (the X direction shown in the figure).

Specifically, generally, the film in which the data line 122 is located is not the same as the film in which the fan-out data line 111 is located so that when the fan-out data line 111 is electrically connected to the data line 122, the electrical connection needs to be performed by punching. That is, the data line 122 is electrically connected to the data line 111 through a connection via 14. For the case where the display resolution of the display panel is higher, the distance between two data lines 122 adjacent to each other in the second direction (the Z direction shown in the figure) is limited, and the size of a connection via 14 cannot be indefinitely reduced due to the limitation of the via process. Since the data lines 122 connected to the fan-out data lines 111 in the same fan-out data line group 11a are adjacent in the second direction, to prevent a short circuit problem among different fan-out data lines 111 or among different data lines 122 caused by via connection due to an insufficient space for disposing two adjacent connection vias 14 when the fan-out data lines 111 in the same fan-out data line group 11a are electrically connected to the data lines 122 adjacent in the second direction, the configuration in which the connection vias through which the fan-out data lines 111 in the same fan-out data line group 11a are connected to the data lines 122 are staggered in the first direction (the X direction shown in the figure) is inventively provided in this embodiment of the present disclosure. In this manner, the electrical connection relationship between the fan-out data lines 111 and the data lines 122 cannot be affected while the distance between the two adjacent data lines 122 does not need to be increased due to the space for disposing the connection via 14 so that the display resolution of the display panel cannot be affected, and the normal transmission of a data signal and the normal display of the display panel can be ensured.

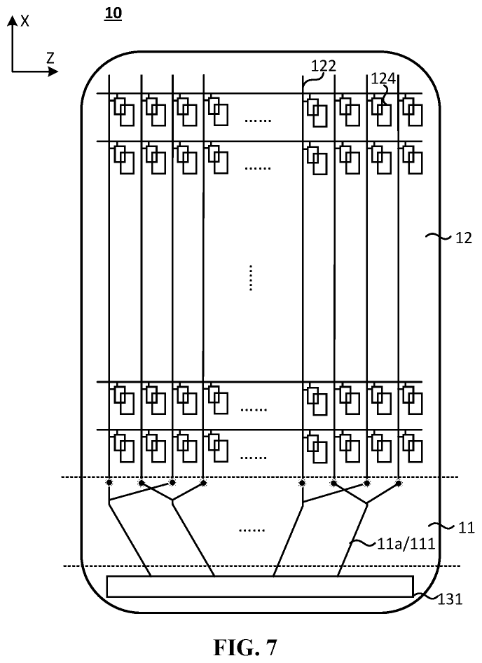

Based on the preceding embodiment, FIG. 7 is a diagram illustrating the structure of another display panel according to embodiments of the present disclosure. As shown in FIG. 7, the display panel 10 also includes a display region 12, and the fan-out region 11 is located on one side of the display region 12; the display panel 10 also includes data lines 122 located in the display region 12, and the data lines 122 extend in the first direction (the X direction shown in the figure) and are arranged in the second direction (the Z direction shown in the figure); and among the data lines 122, data lines connected to the fan-out data lines 111 in the same fan-out data line group 11a are nonadjacent in the second direction.

Specifically, as shown in FIG. 7, the display panel 10 also includes a display region 12 and data lines 122 located in the display region 12. The data lines 122 extend in the first direction (the X direction shown in the figure) and are arranged in the second direction (the Z direction shown in the figure). A fan-out data line 111 is electrically connected to data lines 12 and the driver chip 131 so that a data signal supplied by the driver chip 131 can be transmitted to the data lines 122 through the fan-out data line 111 to drive light-emitting sub-pixels 124 to normally emit light for display. In this embodiment of the present disclosure, the data lines 122 connected to the fan-out data lines 111 in the same fan-out data line group 11a are nonadjacent in the second direction so that the electrical connection relationship between the fan-out data lines 111 and the data lines 122 can be flexible without the need to limit that the fan-out data lines 111 in the same fan-out data line group 11a are connected to the data lines 122 adjacent in the second direction or without the need to limit that the data lines 122 adjacent in the second direction are connected to the fan-out data lines 111 in the same fan-out data line group 11a, and the connection relationship between the fan-out data lines 111 and the data lines 122 can be flexibly adjusted according to different needs in the display panel. For example, a fan-out data line having a smaller sheet resistance may be selected to be electrically connected to a data line corresponding to a light-emitting sub-pixel having a lower luminescence efficiency so that the overall display of the display panel can be well balanced by compensating for the luminescence efficiency of the light-emitting sub-pixel by a smaller loss in the fan-out data line.

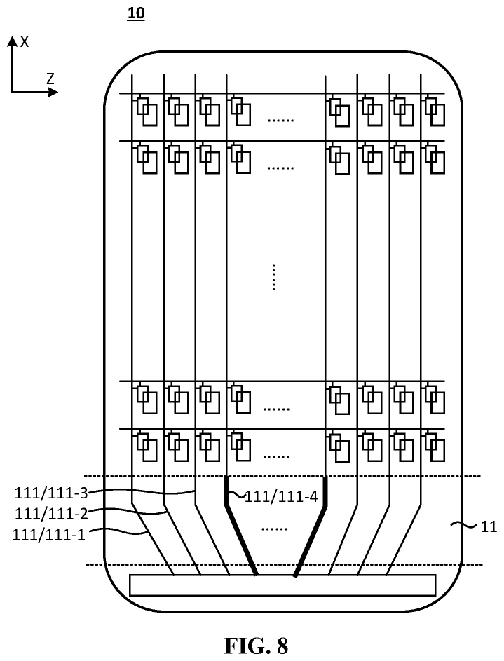

In an embodiment, FIG. 8 is a diagram illustrating the structure of another display panel according to embodiments of the present disclosure. As shown in FIG. 8, among the at least three layers of fan-out data lines 111, fan-out data lines 111 disposed in different layers are located in films having different sheet resistances; and among any two of the fan-out data lines 111 disposed in different layers, a fan-out data line 111 having a larger sheet resistance has a larger line width than a fan-out data line 111 having a smaller sheet resistance.

Specifically, FIG. 8 illustrates that the at least three layers of fan-out data lines 111 include four layers of fan-out data lines, for example, 111-1, 111-2, 111-3, and 111-4. Sheet resistances represent the properties of different films. Fan-out data lines in different films have different sheet resistances. The sheet resistances may be related to the film materials or the film thickness of the fan-out data lines. For example, the film in which the fan-out data line 111-4 is located may have a larger sheet resistance, and the loss produced when a data signal is transmitted on the fan-out data line 111-4 is larger than the losses produced when the data signal is transmitted on other fan-out data lines, so the fan-out data line 111 having a larger sheet resistance may be configured to have a larger line width than the fan-out data line 111 having a smaller sheet resistance. For example, the fan-out data line 111-4 has a larger line width than the fan-out data line 111-1, the fan-out data line 111-2, and the fan-out data line 111-3. In this manner, by a larger line width, the resistance of the fan-out data line 111-1 can be reduced, the loss can be reduced when a signal is transmitted on the fan-out data line 111-4, and the signal transmission effect can be improved. Meanwhile, the fan-out data line 111 having a larger sheet resistance is configured to have a larger line width than the fan-out data line 111 having a smaller sheet resistance so that by compensating for the sheet resistance differences of the fan-out data lines by the line width differences of the fan-out data lines, the losses in transmission processes of a signal on different fan-out data lines can be the same or similar, and the display of the display panel can be well balanced.

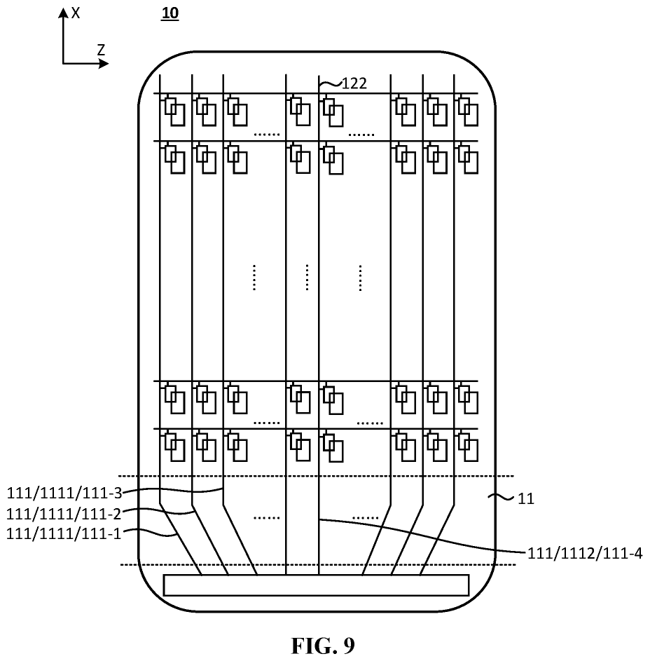

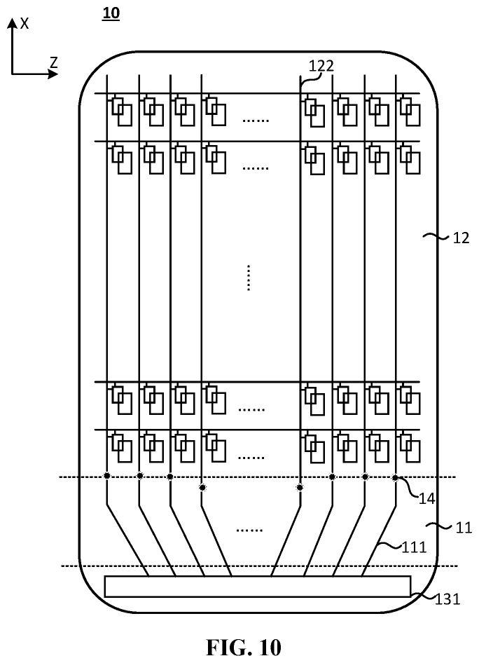

In an embodiment, FIG. 9 is a diagram illustrating the structure of another display panel according to embodiments of the present disclosure, and FIG. 10 is a diagram illustrating the structure of another display panel according to embodiments of the present disclosure. As shown in FIGS. 9 and 10, among the at least three layers of fan-out data lines 111, fan-out data lines 111 disposed in different layers are located in films having different sheet resistances; and among any two of the fan-out data lines 111 disposed in different layers, a fan-out data line 111 having a larger sheet resistance has a smaller extension length than a fan-out data line 111 having a smaller sheet resistance.

Specifically, FIG. 9 illustrates that the at least three layers of fan-out data lines 111 include four layers of fan-out data lines, for example, 111-1, 111-2, 111-3, and 111-4. Sheet resistances represent the properties of different films. Fan-out data lines in different films have different sheet resistances. The sheet resistances may be related to the film materials or the film thickness of the fan-out data lines. For example, the film in which the fan-out data line 111-4 is located may have a larger sheet resistance, and the loss produced when a data signal is transmitted on the fan-out data line 111-4 may be larger than the losses produced when the data signal is transmitted on other fan-out data lines, so the fan-out data line 111 having a larger sheet resistance may be configured to have a smaller extension length than the fan-out data line 111 having a smaller sheet resistance. For example, the fan-out data line 111-4 is configured to have a smaller extension length than the fan-out data line 111-1, the fan-out data line 111-2, and the fan-out data line 111-3. In this manner, by a smaller extension length, the resistance of the fan-out data line 111-1 can be reduced, the loss can be reduced when a signal is transmitted on the fan-out data line 111-4, and the signal transmission effect can be improved. Meanwhile, the fan-out data line 111 having a larger sheet resistance is configured to have a smaller extension length than the fan-out data line 111 having a smaller sheet resistance so that by compensating for the sheet resistance differences of the fan-out data lines by the extension length differences of the fan-out data lines, the losses in transmission processes of a signal on different fan-out data lines can be the same or similar, and the display of the display panel can be well balanced.

Based on the preceding embodiment, with continued reference to FIG. 9, the fan-out region 111 includes an edge fan-out data line 1111 located at the edge of the fan-out region and a center fan-out data line 1112 located in the center of the fan-out region; the fan-out data line 111 having a larger sheet resistance includes the center fan-out data line 1112; and the fan-out data line 111 having a smaller sheet resistance includes the edge fan-out data line 1111.

As shown in FIG. 9, the fan-out region 11 may include an edge region and a center region. The edge region is located on one side of the center region facing the edge of the fan-out region. The center region is located on one side of the edge region facing the center of the fan-out region. Further, a fan-out data line 111 located at the edge of the fan-out region may also serve as the edge fan-out data line 1111, and a fan-out data line 111 located in the center of the fan-out region may also serve as the center fan-out data line 1112. According to the relative positional relationship between the driver chip 131 and the display region 12, the center fan-out data line 1112 may include only a wiring portion that is the same as the extension direction of the data lines 122, and the extension length is smaller; and the edge fan-out data line 1111 includes a wiring portion that is the same as the extension direction of the data lines 122 and a wiring portion that intersects the extension direction of the data lines 122, and the extension length is larger, as shown in FIG. 9. Alternatively, the center fan-out data line 1112 includes a wiring portion that is the same as the extension direction of the data lines 122 and a wiring portion that intersects the extension direction of the data lines 122, but the wiring portion that intersects the extension direction of the data lines 122 has a larger slope, and the extension length is smaller; and the edge fan-out data line 1111 includes a wiring portion that is the same as the extension direction of the data lines 122 and a wiring portion that intersects the extension direction of the data lines 122, but the wiring portion that intersects the extension direction of the data lines 122 has a smaller slope, and the extension length is larger. In this manner, the edge fan-out data line 1111 has a larger extension length, and the center fan-out data line 1112 has a smaller extension length.

Further, the fan-out data line 111 having a larger sheet resistance is configured to have a smaller extension length than the fan-out data line 111 having a smaller sheet resistance, and the losses in transmission processes of a signal on different fan-out data lines may be the same or similar by compensating for the sheet resistance differences of the fan-out data lines by the extension length differences of the fan-out data lines, so the fan-out data line 111 having a larger sheet resistance can be configured to include the center fan-out data line 1112, and the fan-out data line 111 having a smaller sheet resistance can be configured to include the edge fan-out data line 1111. In this manner, the normal configuration requirement on the fan-out data lines can be satisfied while by compensating for the sheet resistance differences of the fan-out data lines by the extension length differences of the fan-out data lines, the losses in transmission processes of a signal on different fan-out data lines can be the same or similar, and the display can be well balanced.

It is to be noted that the edge region of the fan-out region and the center region of the fan-out region are disposed relatively, the edge region of the fan-out region is located at the edge of the fan-out region relative to the center region of the fan-out region, and the center region of the fan-out region is located in the center of the fan-out region relative to the edge region of the fan-out region. The specific configuration position of the edge region of the fan-out region and the specific configuration position of the center region of the fan-out region are not limited in this embodiment of the present disclosure. Similarly, the edge fan-out data line and the center fan-out data line are disposed relatively, the edge fan-out data line is located at the edge of the fan-out region relative to the center fan-out data line, and the center fan-out data line is located in the center of the fan-out region relative to the edge fan-out data line. The specific configuration position of the edge fan-out data line and the specific configuration position of the center fan-out data line are not limited in this embodiment of the present disclosure.

Based on the preceding embodiment, with continued reference to FIG. 10, the display panel 10 also includes a display region 12, and the fan-out region 11 is located on one side of the display region 12; the display panel 10 also includes data lines 122 located in the display region 12, and the data lines 122 extend in the first direction (the X direction shown in the figure) and are arranged in the second direction (the Z direction shown in the figure), and a data line 122 is electrically connected to a fan-out data line 111 through a connection via 14; and in the first direction (the X direction shown in the figure), a connection via 14 between the fan-out data line 111 having a larger sheet resistance and a data line connected to the fan-out data line having a larger sheet resistance is located on one side of a connection via 14 between the fan-out data line 111 having a smaller sheet resistance and a data line connected to the fan-out data line 111 having a smaller sheet resistance, where the one side faces the fan-out region 11.

Specifically, as shown in FIG. 10, the display panel 10 also includes a display region 12 and multiple data lines 122 located in the display region 12. The multiple data lines 122 extend in the first direction (the X direction shown in the figure) and are arranged in the second direction (the Z direction shown in the figure). A fan-out data line 111 is electrically connected to a data line 12 and the driver chip 131 so that a data signal supplied by the driver chip 131 can be transmitted to the data line 122 through the fan-out data line 111 to drive light-emitting sub-pixels 124 to normally emit light for display. Generally, the film in which the data line 122 is located is not the same as the film in which the fan-out data line 111 is located so that when the fan-out data line 111 is electrically connected to the data line 122, the electrical connection needs to be performed by punching. That is, the data line 122 is electrically connected to the fan-out data line 111 through a connection via 14.

Further, FIG. 10 illustrates that the at least three layers of fan-out data lines 111 include four layers of fan-out data lines, for example, 111-1, 111-2, 111-3, and 111-4. Sheet resistances represent the properties of different films. Fan-out data lines in different films have different sheet resistances. The sheet resistances may be related to the film materials or the film thickness of the fan-out data lines. For example, the film in which the fan-out data line 111-4 is located may have a larger sheet resistance, and the loss produced when a data signal is transmitted on the fan-out data line 111-4 is larger than the losses produced when the data signal is transmitted on other fan-out data lines, so in the first direction (the X direction shown in the figure), a connection via 14 between the fan-out data line 111 having a larger sheet resistance and the data line 122 connected to the fan-out data line 111 having a larger sheet resistance may be configured to be located on one side of the connection via 14 between the fan-out data line 111 having a smaller sheet resistance and the data line 122 connected to the fan-out data line 111 having a smaller sheet resistance, where the one side faces the fan-out region 11. For example, the connection via 14 between the fan-out data line 111-4 and a data line 122 connected to the fan-out data line 111-4 is located on one side of the connection via 14 between the fan-out data line 111-1 and a data line 122 connected to the fan-out data line 111-1, where the one side faces the fan-out region 11, on one side of the connection via 14 between the fan-out data line 111-2 and a data line 122 connected to the fan-out data line 111-2, where the one side faces the fan-out region 11, and on one side of the connection via 14 between the fan-out data line 111-3 and a data line 122 connected to the fan-out data line 111-3, where the one side faces the fan-out region 11. That is, a signal transmitted on the fan-out data line 111-4 enters the data line 122 earlier so that the transmission path of the signal on the fan-out data line 111-4 can be reduced, and the transmission path of the signal on the data line 122 can be extended. Since the data line 122 has a smaller sheet resistance, the loss can be reduced when the signal is transmitted on the fan-out data line 111-4, and the signal transmission effect can be improved. Meanwhile, in the first direction (the X direction shown in the figure), the connection via 14 between the fan-out data line 111 having a larger sheet resistance and the data line 122 connected to the fan-out data line 111 having a larger sheet resistance is configured to be located on the one side of the connection via 14 between the fan-out data line 111 having a smaller sheet resistance and the data line 122 connected to the fan-out data line 111 having a smaller sheet resistance, where the one side faces the fan-out region 11 so that by adjusting the transmission loss of a signal on a fan-out data line by the position of a connection via 14, the losses in transmission processes of a signal on different fan-out data lines and different data lines can be the same or similar, and the display of the display panel can be well balanced.

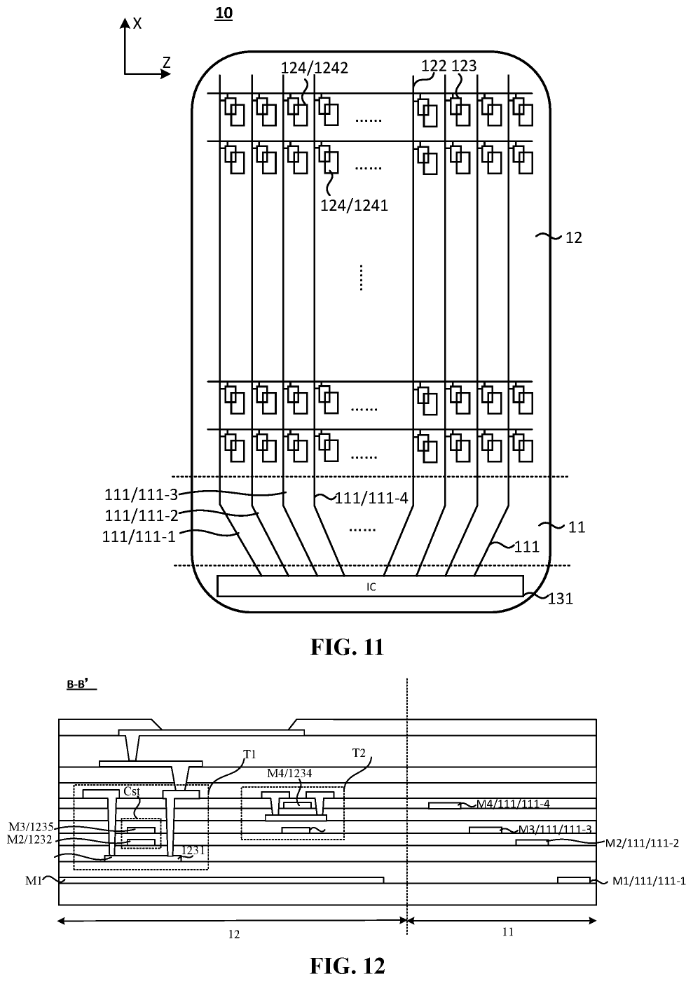

In an embodiment, FIG. 11 is a diagram illustrating the structure of another display panel according to embodiments of the present disclosure. As shown in FIG. 11, the display panel 10 also includes a display region 12, and the fan-out region 11 is located on one side of the display region 12; the display region 12 also includes data lines 122 and light-emitting sub-pixels 124, and a fan-out data line 111 is electrically connected to light-emitting sub-pixels 124 through a data line 122; among the at least three layers of fan-out data lines 111, fan-out data lines 111 disposed in different layers are located in films having different sheet resistances; and among any two of the fan-out data lines 111 disposed in different layers, a fan-out data line 111 having a larger sheet resistance is connected to a light-emitting sub-pixel 124 having a luminescence efficiency larger than the luminescence efficiency of a light-emitting sub-pixel 124 connected to a fan-out data line 111 having a smaller sheet resistance.

Specifically, as shown in FIG. 11, the display panel 10 also includes a display region 12, data lines 122, pixel circuits 123, and light-emitting sub-pixels 124 that are located in the display region 12. A fan-out data line 111 is electrically connected to a data line 12 and the driver chip 131, and the data line 122 is electrically connected to light-emitting sub-pixels 124 through pixel circuits 123 so that a data signal supplied by the driver chip 131 can be transmitted to the data line 122 through the fan-out data line 111 and then to the light-emitting sub-pixels 124 through the pixel circuits 123 to drive the light-emitting sub-pixels 124 to normally emit light for display.

Further, FIG. 11 illustrates that the at least three layers of fan-out data lines 111 include four layers of fan-out data lines, for example, 111-1, 111-2, 111-3, and 111-4. Sheet resistances represent the properties of different films. Fan-out data lines in different films have different sheet resistances. The sheet resistances may be related to the film materials or the film thickness of the fan-out data lines. For example, the film in which the fan-out data line 111-4 is located may have a larger sheet resistance, and the loss produced when a data signal is transmitted on the fan-out data line 111-4 is larger than the losses produced when the data signal is transmitted on other fan-out data lines. Meanwhile, there is a difference among the luminescence efficiencies of light-emitting sub-pixels having different emitted colors. For example, for a light-emitting sub-pixel of the organic light-emitting diode type, the green sub-pixel has a higher luminescence efficiency. FIG.11 illustrates that the light-emitting sub-pixel 1241 has a luminescence efficiency larger than the luminescence efficiency of the light-emitting sub-pixel 1242. Therefore, in combination with the sheet resistance differences of the multiple fan-out data lines 111 and the luminescence efficiency differences of the multiple light-emitting sub-pixels 124, among any two of the fan-out data lines 111 disposed in different layers, the fan-out data line 111 having a larger sheet resistance may be configured to be connected to the light-emitting sub-pixel 124 having a luminescence efficiency larger than the luminescence efficiency of the light-emitting sub-pixel 124 connected to the fan-out data line 111 having a smaller sheet resistance. For example, the fan-out data line 111-4 is configured to be electrically connected to a light-emitting sub-pixel 124 having a higher luminescence efficiency, the fan-out data line 111-1, the fan-out data line 111-2 and the fan-out data line 111-3 are configured to be each electrically connected to a light-emitting sub-pixel 124 having a lower luminescence efficiency. In this manner, the display of the display panel can be well balanced by compensating for the sheet resistance differences of the multiple fan-out data lines 111 by the luminescence efficiency differences of the multiple light-emitting sub-pixels 124.

It is to be noted that the fan-out data line 111 having a larger sheet resistance connected to the light-emitting sub-pixel 124 may be understood as that the fan-out data line 111 having a larger sheet resistance is connected to the light-emitting sub-pixel 124 through a data line 122 and a pixel circuit 123.

In conclusion, when the fan-out data lines disposed in different layers are located in films having different sheet resistances, how to reasonably dispose the configuration mode of the fan-out data lines, how to reasonably dispose the connection mode between the fan-out data lines and the data lines, and how to reasonably dispose the configuration mode of the fan-out data lines and the light-emitting sub-pixels are illustrated in the preceding embodiments. By reasonably disposing the configuration mode of the fan-out data lines, the connection mode between the fan-out data lines and the data lines, and the connection mode between the fan-out data lines and the light-emitting sub-pixels, the display unevenness caused by the sheet resistance differences of the fan-out data lines can be compensated for so that the display of the display panel can be well balanced.

The specific configuration mode of multiple layers of fan-out data lines disposed in different layers is illustrated below in combination with the actual configuration mode in the display panel.

With continued reference to FIGS. 1 to 11, the fan-out data lines 111 include a first fan-out data line 111-1, a second fan-out data line 111-2, a third fan-out data line 111-3, and a fourth fan-out data line 111-4 that are disposed in different layers.

Specifically, the fan-out data lines 111 include a first fan-out data line 111-1, a second fan-out data line 111-2, a third fan-out data line 111-3, and a fourth fan-out data line 111-4 that are disposed in different layers, that is, the existing fan-out data lines disposed in the same layer are disposed in four different layers, so that the space for disposing the fan-out data lines 111 can be fully reduced by a stacking design, the narrow bezel design of the display panel can be fully achieved, and thereby the screen-to-body ratio of the display panel can be fully increased.

Based on this, FIG. 12 is a sectional view of the structure of the display panel of FIG. 1 taken along section line B-B′. In combination with FIG. 1 and FIG. 12, the display region 12 includes multiple pixel circuits 123, and a pixel circuit 123 includes a first thin-film transistor T1, a second thin-film transistor T2, and a storage capacitor Cst. The first thin-film transistor T1 includes a polycrystalline active layer 1231 and a first gate 1232. The second thin-film transistor T2 includes an oxide active layer 1233 and a second gate 1234. The storage capacitor Cst includes a capacitive substrate 1235. The second fan-out data line 111-2 and the first gate 1232 are disposed in the same layer. The third fan-out data line 111-3 and the capacitive substrate 1235 are disposed in the same layer. The fourth fan-out data line 111-4 and the second gate 1234 are disposed in the same layer. The first fan-out data line 111-1 is located on a side of the second fan-out data line 111-2 facing a base substrate 15.

Specifically, as shown in FIG. 12, the first thin-film transistor T1 includes a polycrystalline active layer 1231. For example, the first thin-film transistor T1 may be a low-temperature polycrystalline silicon (LTPS) transistor, with the advantages of high switching speed, high carrier mobility, and low power consumption. The second thin-film transistor T2 includes an oxide active layer 1233. For example, the second thin-film transistor T2 may be an indium gallium zinc oxide (IGZO) transistor, with the advantages of a small preparation leakage current and stable performance. The pixel circuit 123 according to this embodiment of the present disclosure includes both the first thin-film transistor T1 and the second thin-film transistor T2, that is, a pixel circuit of the low-temperature polycrystalline oxide (LTPO) type, so that the advantages of different transistors can be fully used for ensuring excellent performance and high driving efficiency of the pixel circuit 123.

Further, the pixel circuit 123 may include a first metal layer M1, a second metal layer M2, a third metal layer M3, and a fourth metal layer M4. The first metal layer M1 includes the first fan-out data line 111-1, the second metal layer M2 includes the first gate 1232 and the second fan-out data line 111-2, the third metal layer M3 includes the capacitive substrate 1235 and the third fan-out data line 111-3, and the fourth metal layer M4 includes the second gate 1234 and the fourth fan-out data line 111-4. That is, the second fan-out data line 111-2 and the first gate 1232 are disposed in the second metal layer M2, the third fan-out data line 111-3 and the capacitive substrate 1235 are disposed in the third metal layer M3, the fourth fan-out data line 111-4 and the second gate 1234 are disposed in the fourth metal layer M4, and the first fan-out data line 111-1 is located in the first metal layer M1 located on a side of the second fan-out data line 111-2 facing the base substrate 15. In this manner, the four layers of fan-out data lines 111 disposed in different layers and the metal layers in the existing display panel are disposed in the same layer and can be prepared in the same mask process so that the four layers of fan-out data lines 111 disposed in different layers can be simple in the configuration mode and the preparation process and can differently increase the film structures of the display panel, thereby ensuring that the display panel can be lighter and thinner. Further, the first metal layer M1 is disposed between the pixel circuit 123 and the base substrate 15 and may block light incident on the pixel circuit 123 from the back of the display panel 10. For example, the first metal layer M1 blocks light incident on the polycrystalline active layer 1231, thereby preventing a leakage current from being generated in the polycrystalline active layer 1231 due to light, ensuring that the polycrystalline active layer 1231 can be prevented from the effect of light, and ensuring the good display precision of the display.

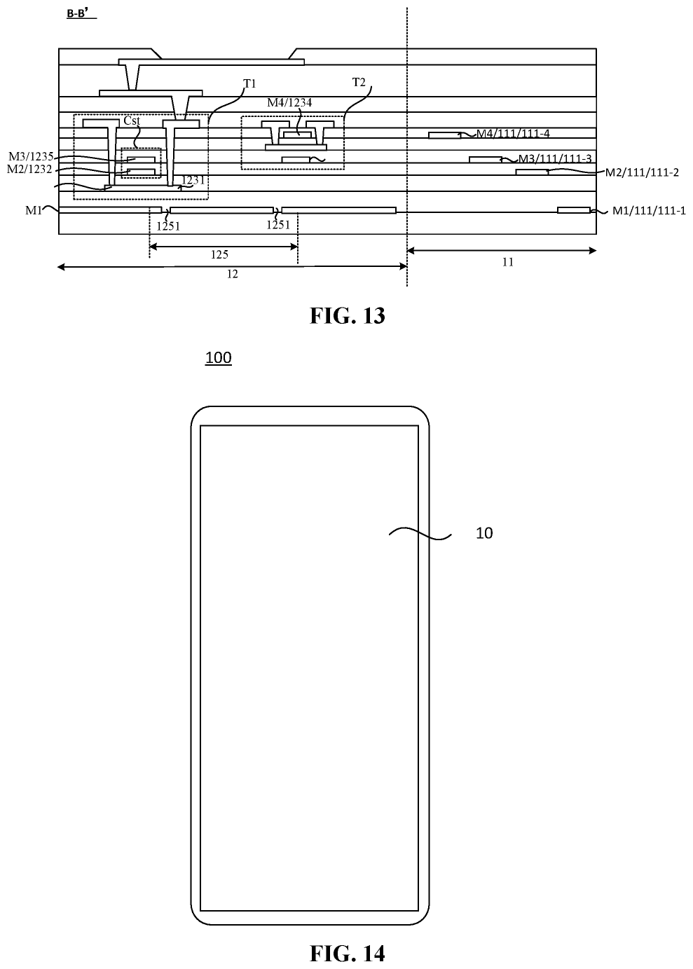

Based on the preceding embodiment, FIG. 13 is another sectional view of the structure of the display panel of FIG. 1 taken along section line B-B′. As shown in FIG. 13, the display region 12 may also include a photosensitive display region 125; the photosensitive display region 125 includes photosensitive apertures 1251; and the film in which the first fan-out data line 111-1 is located is the same as the film in which the photosensitive apertures 1251 are located.

Specifically, as shown in FIG. 13, the display region 12 according to this embodiment of the present disclosure may also include a photosensitive display region 125. The photosensitive display region 125 may receive recognition light and perform optical recognition based on the recognition light. Specifically, the photosensitive display region 125 may be an imaging display region, and correspondingly, the recognition light may be light reflected by an external to-be-imaged object, or the photosensitive display region 125 may be a fingerprint recognition region, and correspondingly, the recognition light may be light carrying a finger texture signal. In this embodiment of the present disclosure, the specific type of the photosensitive display region 125 is not limited, as long as the photosensitive display region 125 can perform optical recognition based on the recognition light.

Further, the photosensitive display region 125 includes multiple photosensitive apertures 1251 for transmitting recognition light so that the recognition light can be incident on a photosensitive structure, for example, a camera or a fingerprint recognition chip. Further, the film in which the first fan-out data line 111-1 is located is the same as the film in which the multiple photosensitive apertures 125 are located, that is, the multiple photosensitive apertures 1251 are disposed in the first metal layer M1. The multiple photosensitive apertures 125 are specifically light-transmissive apertures obtained by performing a patterning process on the first metal layer M1. In this manner, on one hand, the multiple photosensitive apertures 125 can be simple in the configuration mode and the preparation process, and on the other hand, by adding the multiple photosensitive apertures 125 in the first metal layer M1, the optical recognition function of the display panel can be fulfilled, and thereby the functional integration of the display panel can be improved.

Based on the inventive concept as described in the preceding, embodiments of the present disclosure also provide a display device. FIG. 14 is a diagram illustrating the structure of a display device according to embodiments of the present disclosure. As shown in FIG. 14, the display device 100 includes the display panel 10 in the preceding embodiments. The display device includes the display panel described in any embodiment of the present disclosure. Therefore, the display device according to this embodiment of the present disclosure has the corresponding beneficial effects of the display panel according to the embodiments of the present disclosure. The details are not repeated here. Exemplarily, the display device may be an electronic device such as a mobile phone, a computer, a smart wearable device (for example, a smart watch), or an onboard display device. This is not limited in this embodiment of the present disclosure.

It is to be noted that the preceding are preferred embodiments of the present disclosure and the technical principles used therein. It is to be understood by those skilled in the art that the present disclosure is not limited to the embodiments described herein. For those skilled in the art, various apparent modifications, adaptations, combinations, and substitutions can be made without departing from the scope of the present disclosure. Therefore, while the present disclosure has been described in detail via the preceding embodiments, the present disclosure is not limited to the preceding embodiments and may include more equivalent embodiments without departing from the inventive concept of the present disclosure. The scope of the present disclosure is determined by the scope of the appended claims.

What is claimed is:

1. A display panel, comprising a fan-out region, wherein the fan-out region comprises a plurality of fan-out data lines, and the plurality of fan-out data lines comprise at least three layers of fan-out data lines disposed in different layers.

2. The display panel according to claim 1, wherein any two of the at least three layers of fan-out data lines disposed in different layers are staggered in a thickness direction of the display panel.

3. The display panel according to claim 1, wherein two of the at least three layers of fan-out data lines disposed in different layers overlap in a thickness direction of the display panel.

4. The display panel according to claim 3, wherein the fan-out region comprises at least two fan-out data line groups, and each of the at least two fan-out data line groups comprises at least two layers of fan-out data lines; and
in the thickness direction of the display panel, fan-out data lines in a same fan-out data line group of the at least two fan-out data line groups overlap, and fan-out data lines in different fan-out data line groups of the at least two fan-out data line groups are staggered.

5. The display panel according to claim 4, wherein for each of the at least two fan-out data line groups, a space between two layers of fan-out data lines adjacent to each other in the thickness direction of the display panel and comprised in a fan-out data line group of the at least two fan-out data line groups contains fan-out data lines in another fan-out data line group of the at least two fan-out data line groups.

6. The display panel according to claim 4, further comprising a display region, wherein the fan-out region is located on one side of the display region;
the display panel further comprises a plurality of data lines located in the display region, wherein the plurality of data lines extend in a first direction and are arranged in a second direction; and
among the plurality of data lines, data lines connected to the fan-out data lines in the same fan-out data line group are adjacent in the second direction.

7. The display panel according to claim 6, wherein a data line of the plurality of data lines is electrically connected to a fan-out data line of the plurality of fan-out data lines through a connection via; and
connection vias through which the fan-out data lines in the same fan-out data line group are connected to the data lines are staggered in the first direction.

8. The display panel according to claim 4, further comprising a display region, wherein the fan-out region is located on one side of the display region;
the display panel further comprises a plurality of data lines located in the display region, wherein the plurality of data lines extend in a first direction and are arranged in a second direction; and
among the plurality of data lines, data lines connected to the fan-out data lines in the same fan-out data line group are nonadjacent in the second direction.

9. The display panel according to claim 1, wherein among the at least three layers of fan-out data lines, fan-out data lines disposed in different layers are located in films having different sheet resistances; and
among any two of the fan-out data lines disposed in different layers, a fan-out data line having a larger sheet resistance has a larger line width than a fan-out data line having a smaller sheet resistance.

10. The display panel according to claim 1, wherein among the at least three layers of fan-out data lines, fan-out data lines disposed in different layers are located in films having different sheet resistances; and
among any two of the fan-out data lines disposed in different layers, a fan-out data line having a larger sheet resistance has a smaller extension length than a fan-out data line having a smaller sheet resistance.

11. The display panel according to claim 10, wherein the fan-out region comprises an edge fan-out data line located at an edge of the fan-out region and a center fan-out data line located in a center of the fan-out region;
the fan-out data line having the larger sheet resistance comprises the center fan-out data line; and
the fan-out data line having the smaller sheet resistance comprises the edge fan-out data line.

12. The display panel according to claim 10, further comprising a display region, wherein the fan-out region is located on one side of the display region;
the display panel further comprises a plurality of data lines located in the display region, wherein the plurality of data lines extend in a first direction and are arranged in a second direction, a data line of the plurality of data lines is electrically connected to a fan-out data line of the plurality of fan-out data lines through a connection via; and
in the first direction, a connection via between the fan-out data line having the larger sheet resistance and a data line connected to the fan-out data line having the larger sheet resistance is located on one side of a connection via between the fan-out data line having the smaller sheet resistance and a data line connected to the fan-out data line having the smaller sheet resistance, wherein the one side faces the fan-out region.

13. The display panel according to claim 1, further comprising a display region, wherein the fan-out region is located on one side of the display region;
the display region further comprises a plurality of data lines and a plurality of light-emitting sub-pixels, and a fan-out data line of the plurality of fan-out data lines is electrically connected to a light-emitting sub-pixel of the plurality of light-emitting sub-pixels through a data line of the plurality of data lines;
among the at least three layers of fan-out data lines, fan-out data lines disposed in different layers are located in films having different sheet resistances; and
among any two of the fan-out data lines disposed in different layers, a fan-out data line having a larger sheet resistance is connected to a light-emitting sub-pixel having a luminescence efficiency larger than a luminescence efficiency of a light-emitting sub-pixel connected to a fan-out data line having a smaller sheet resistance.

14. The display panel according to claim 1, wherein the plurality of fan-out data lines comprise a first fan-out data line, a second fan-out data line, a third fan-out data line, and a fourth fan-out data line that are disposed in different layers.

15. The display panel according to claim 14, wherein the display region comprises a plurality of pixel circuits, and a pixel circuit of the plurality of pixel circuits comprises a first thin-film transistor, a second thin-film transistor, and a storage capacitor;
the first thin-film transistor comprises a polycrystalline active layer and a first gate, the second thin-film transistor comprises an oxide active layer and a second gate, and the storage capacitor comprises a capacitive substrate; and
the second fan-out data line and the first gate are disposed in a same layer, the third fan-out data line and the capacitive substrate are disposed in a same layer, the fourth fan-out data line and the second gate are disposed in a same layer, and the first fan-out data line is located on a side of the second fan-out data line facing a base substrate.

16. The display panel according to claim 15, wherein the display region comprises a photosensitive display region;
the photosensitive display region comprises a photosensitive aperture; and
a film in which the first fan-out data line is located is the same as a film in which the photosensitive aperture is located.

17. A display device, comprising a display panel, wherein the display panel comprises a fan-out region, the fan-out region comprises a plurality of fan-out data lines, and the plurality of fan-out data lines comprise at least three layers of fan-out data lines disposed in different layers.

18. The display device according to claim 17, wherein any two of the at least three layers of fan-out data lines disposed in different layers are staggered in a thickness direction of the display panel.

19. The display device according to claim 17, wherein two of the at least three layers of fan-out data lines disposed in different layers overlap in a thickness direction of the display panel.

20. The display panel according to claim 19, wherein the fan-out region comprises at least two fan-out data line groups, and each of the at least two fan-out data line groups comprises at least two layers of fan-out data lines; and
in the thickness direction of the display panel, fan-out data lines in a same fan-out data line group of the at least two fan-out data line groups overlap, and fan-out data lines in different fan-out data line groups of the at least two fan-out data line groups are staggered.
